(19) United States
(12) Patent Application Publication
(10) Pub. No.: US 2009/0167323 A1
(43) Pub. Date: Jul. 2, 2009

(54) Dynamic Range Recovery for Pulse-Modulated Measurements

(76) Inventor: Robert E. Shoulders, Santa Rosa, CA (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 11/968,009

(22) Filed: Dec. 31, 2007

(51) Int. Cl. G01R 31/28

(52) U.S. Cl. 324/650

(57) ABSTRACT

A system composed of an RF input, a receiver system and, connected in series between the RF input and the receiver, an amplifier, a gate switch and a bandpass filter. The receiver system is operable to determine the characteristic of the DUT based on an RF input signal received from the DUT. The amplifier receives and amplifies the RF input signal to generate an amplified signal at a power level that exceeds the maximum input power of the receiver system. The bandpass filter is configured to select from the gated signal a selected signal comprising a wanted frequency component. The band-pass filter has a rise-time in relation to the ON time of the gate switch such that the selected signal has a maximum power that does not exceed the maximum input power of the receiver system. In another embodiment, the system additionally comprises a mixer interposed between the RF input and the amplifier.

### BACKGROUND

A vector network analyzer (VNA) is used to measure a device under test (DUT) using pulse-modulated signals. In such a measurement, the VNA transmits a pulse-modulated signal to the DUT and the output from the DUT is analyzed by the VNA to determine the DUT's performance. As in all signal measurements, the accuracy of VNA measurements is degraded by undesirable signals that are referred to as thermal noise (referred to as “noise” in the rest of the application), which occurs naturally in the environment. The degrading effect of the noise on measurement accuracy depends on the noise level relative to the signal level. The relationship between signal level and noise level is characterized by a signal-to-noise ratio. A signal with high signal-to-noise ratio is less affected by noise than a signal with low signal-to-noise ratio. To minimize the effect of noise on the measurement accuracy of a signal of narrow pulse width, it is known to use gating techniques to partially eliminate the noise and thereby increase the signal-to-noise ratio. Additionally, adaptive nulling is used to remove unwanted frequency components that result from the pulse-modulated signal.

Some measurements use a pulsed signal having both a small duty cycle and a narrow pulse width. For example, iso-thermal testing on a device measured “on wafer” typically employs a pulsed signal having a narrow pulse width and a small duty cycle. However, measuring a narrow-pulsed signal having a small duty cycle loses at least some of the improvement in the dynamic range obtained by using adaptive nulling and gating techniques.

### BRIEF DESCRIPTION OF THE DRAWINGS

FIG. 1 is a block diagram showing a conventional vector network analyzer VNA that employs adaptive nulling and gating.

FIG. 2A is a block diagram showing an example of a vector network analyzer (VNA) in accordance with an embodiment of the invention.

FIG. 2B is a block diagram showing an example of the receiver system of the VNA shown in FIG. 2A.

FIGS. 3A and 3B are graphs showing the output of the bandpass filter of the VNA shown in FIG. 2A in relation to time when the bandpass filter is subject to pulse inputs of different pulse width.

FIG. 4 is a block diagram showing an example of a VNA in which a mixer is interposed between the RF input and the amplifier in accordance with an embodiment of the invention.

FIG. 5A is a flowchart showing an example of a method in accordance with an embodiment of the invention for determining a characteristic of a DUT from an RF signal received from the DUT.

FIG. 5B is a flowchart showing an example of a method employing signal mixing in accordance with an embodiment of the invention for determining a characteristic of a DUT from an RF signal received from the DUT.

FIG. 6 is a flowchart showing a method for selecting parameters used in the method example shown in FIGS. 5A and 5B.

### DETAILED DESCRIPTION

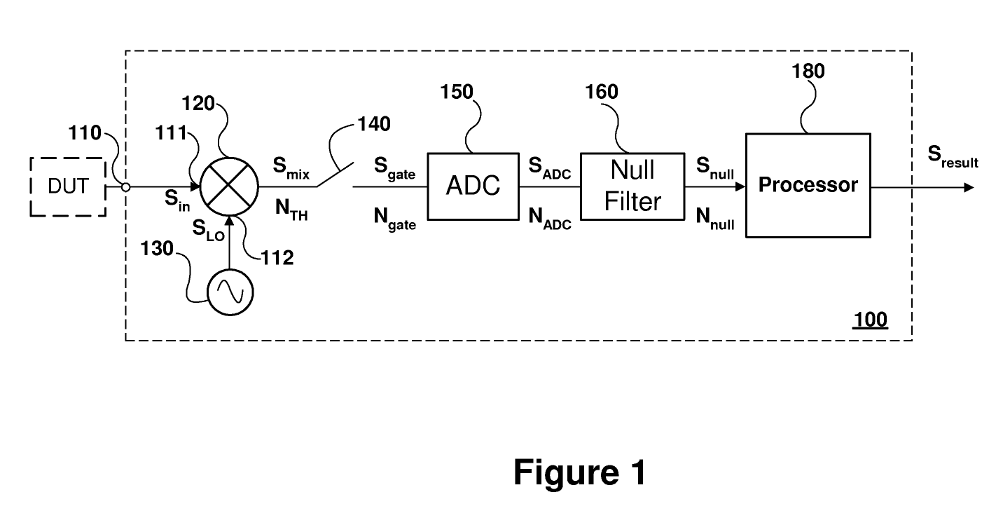

FIG. 1 is a block diagram showing an example a conventional vector network analyzer (VNA) 100 employing adaptive nulling and gating. Conventional VNA 100 is described in more detail in United States patent application publication number 2006/0003723, which is incorporated by reference. The example of the VNA 100 shown is composed of an RF input 110, a mixer 120, a local oscillator (LO) 130, a gate switch 140, an analog-to-digital converter (ADC) 150, a null filter 160 and a processor 180. RF input 110, mixer 120, gate switch 140, ADC 150, null filter 160 and processor 180 are connected in series in the order stated. RF input 110 is connected to receive an RF input signal Sᵢₙ from a device under test (DUT) one or more characteristics of which are subject to measurement by VNA 100. Local oscillator 130 is an oscillator that generates a local-oscillator signal S_{LO}. Mixer 120 has two inputs; a first input 111 and a second input 112. First input 111 is connected to RF input 110 Typically, the RF input signal Sᵢₙ is a pulse-modulated signal. Second input 112 is connected to receive a local-oscillator signal S_{LO} from local oscillator 130. Mixer 120 mixes RF input signal Sᵢₙ and local oscillator signal S_{LO} to generate a broadband mixed signal Sₘᵢₓ.

Gate switch 140 is connected to receive the mixed signal Sₘᵢₓ from mixer 120. Gate switch 120 subjects the mixed signal to repetitive gating to generate a gated signal S_{gate}. ADC 150 is connected to receive the gated signal S_{gate} from gate switch 140. ADC 150 digitizes the gated signal to generate a digital signal S_{ADC}. Null filter 160 is connected to receive the digital signal S_{ADC} from ADC 150. Null filter 160 subjects the digital signal to digital null filtering to generate a filtered signal Sₙᵤₗₗ that represents one or more characteristics of the DUT. The digital null filtering removes undesired frequency components from the digital signal. The undesired frequency components typically include frequency components at frequencies corresponding to the harmonics of the pulse-modulated RF input signal Sᵢₙ. Processor 180 is connected to receive filtered signal Sₙᵤₗₗ from null filter 160. Processor 180 processes the filtered signal to determine the one or more characteristics of the DUT. Processor 180 generates a result signal Sᵣₑₛᵤₗₜ that represents the one or more characteristics of the DUT.

Filtered signal Sₙᵤₗₗ derived from the RF input signal Sᵢₙ has a higher signal-to-noise ratio than mixed signal Sₘᵢₓ that would otherwise be used to determine the one or more characteristics of the DUT in a VNA without gating and nulling. Thus, VNA 100 is capable of measuring the one or more characteristics of the DUT with greater accuracy because VNA 100 is less affected by noise than in a VNA without gating and nulling. However, as noted above, at least some of these benefits are lost when RF input signal Sᵢₙ is a pulse-modulated signal having a small pulse width and a small duty cycle.

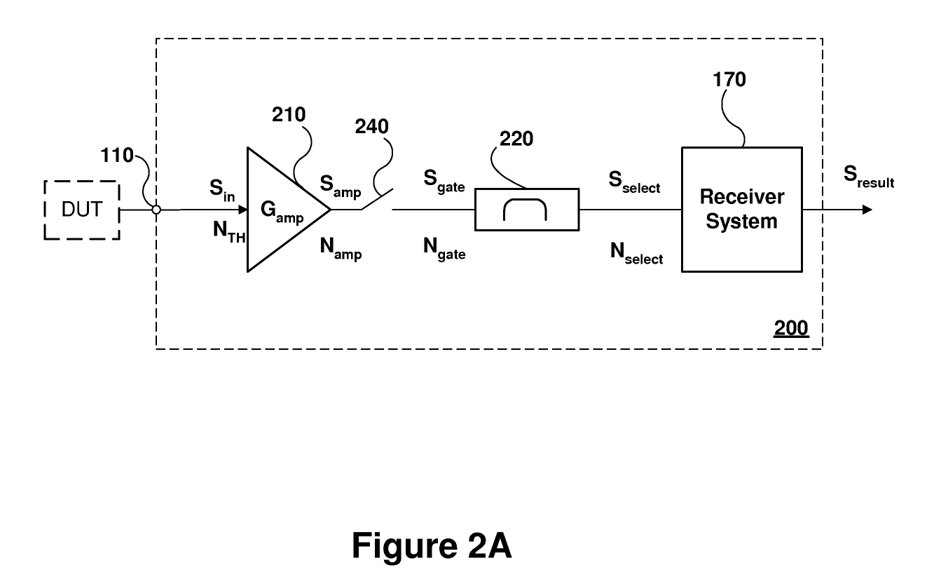

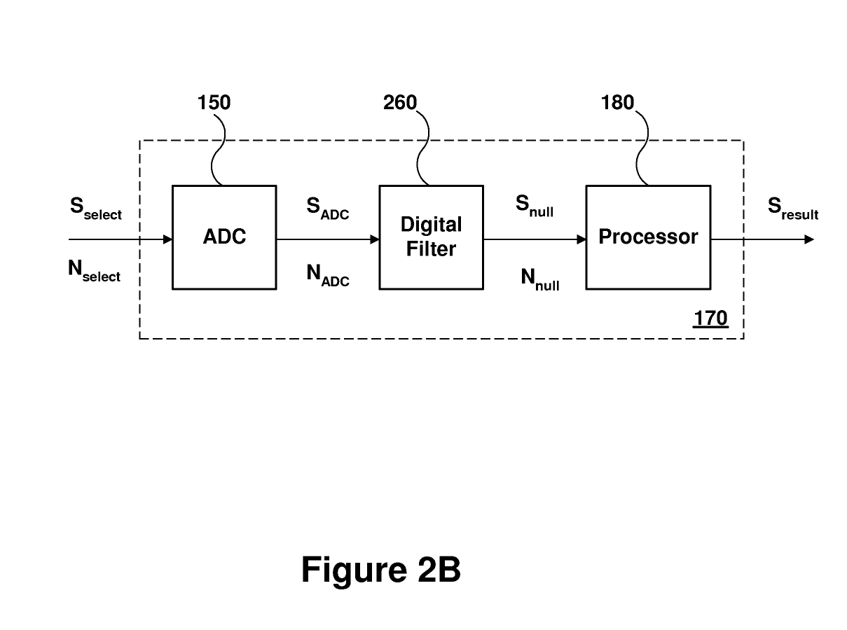

FIG. 2A is a block diagram showing an example of a VNA 200 in accordance with an embodiment of the invention. Elements of VNA 200 corresponding to those of conventional VNA 100 described above with reference to FIG. 1 are indicated using the same reference numerals and will not be described again in detail.

VNA 200 is for determining a characteristic of a device under test (DUT) in response to an RF input signal received from the DUT, and is composed of an RF input 110, a receiver system 170 and circuit elements that include an amplifier 210, a gate switch 240, and a bandpass filter 220. The circuit elements are connected in series between the RF input 110 and the receiver system 170. Receiver system 170 is operable to determine the characteristic of the DUT from a receiver input signal, and has a defined maximum input power. Amplifier 210 is operable to generate an amplified signal by amplifying the RF input signal. The amplified signal has a power level that exceeds the maximum input power of receiver system 170. Bandpass filter 220 is configured to select from the gated signal a selected signal comprising a wanted frequency component. In this embodiment, the wanted frequency component is a frequency component having a frequency equal to that of RF input signal Sᵢₙ. Band-pass filter 220 has a rise-time in relation to the ON time of gate switch 240 such that the selected signal has a maximum power that does not exceed the maximum input power of receiver system 170. The pass band of bandpass filter 220 has a center frequency nominally equal to the frequency of wanted frequency component S_{wanted}. In another embodiment, bandpass filter 220 has a variable pass band that covers the entire bandwidth of the RF input signal.

In some embodiments, the RF input signal Sᵢₙ received from the DUT is a pulse-modulated signal. As will be described below, amplifier 210, gate switch 240 and bandpass filter 220 collectively generate the receiver input signal with a high signal-to-noise ratio even when the RF input signal is a pulse-modulated signal having a small duty cycle and a narrow pulse width.

Amplifier 210 is connected to receive RF input signal Sᵢₙ from RF input 110. Amplifier 210 amplifies the RF input signal by a gain Gₐₘₚ to generate an amplified signal Sₐₘₚ that preserves the pulse envelope of RF input signal Sᵢₙ. Amplified signal Sₐₘₚ has a power greater than the maximum input power level of receiver system 170. Amplified signal Sₐₘₚ is a factor of Gₐₘₚ greater in power than RF input signal Sᵢₙ.

Gate switch 240 is connected to receive amplified signal Sₐₘₚ from amplifier 210. Gate switch 240 subjects the amplified signal to repetitive gating to produce a gated signal S_{gate}. Gate switch 240 is similar to gate switch 140 described above with reference to FIG. 1 and operates with a repetitive operational cycle composed of an ON state and an OFF state. Gate switch 240 differs from gate switch 140 in that, due to the amplification of RF input signal Sᵢₙ by amplifier 210, gate switch 240 has to be capable of handling a greater maximum power without distortion than gate switch 140. Gate switch 240 additionally operates with a duty cycle, which is the ratio between the time W during which gate switch 240 is in its ON state, and the time P taken by the gate switch to execute one operational cycle. In its ON state, gate switch 240 connects the output of amplifier 210 to the input of bandpass filter 220. In its OFF state, gate switch 240 isolates the input of bandpass filter 220 from the output of amplifier 210. Gated signal S_{gate} is the temporal portion of amplified signal Sₐₘₚ output by gate switch 240 during the ON state of each operational cycle.

Bandpass filter 220 is connected to receive gated signal S_{gate} from gate switch 240. Bandpass filter 220 selects the spectral portion of the gated signal S_{gate} that lies within its pass band and outputs the selected portion as a selected signal S_{select}. Selected signal S_{select} comprises a wanted frequency component S_{wanted} and other (typically unwanted) frequency components of gated signal S_{gate} that are within the passband of the bandpass filter.

Receiver system 170 receives selected signal S_{select} from bandpass filter 220 as a receiver input signal. Receiver system 170 subjects the receiver input signal to processing that determines one or more characteristics of the DUT. Receiver system 170 has a defined maximum input power.

FIG. 2B is a block diagram showing an example of the receiver system 170 of the example of VNA 200 shown in FIG. 2A. In the example shown, receiver system 170 is composed of ADC 150, a digital filter 260 and processing system 180 connected in series. ADC 150 is connected to receive selected signal S_{select} from band-pass filter 220. ADC 150 digitizes selected signal S_{select} to generate a digital signal S_{ADC}. Digital signal S_{ADC} comprises wanted frequency component S_{wanted}. In this example, ADC 150 has a full-scale analog input power that defines the maximum input power of receiver system 170. The full-scale analog input power of ADC 150 is the analog input power that causes the ADC to generate a full-scale value of digital signal S_{ADC}.

Digital filter 260 is connected to receive digital signal S_{ADC} from ADC 150. Digital filter 260 generates a filtered signal Sₙᵤₗₗ by subjecting the digital signal S_{ADC} to filtering that attenuates at least some of the remaining unwanted frequency components in digital signal S_{ADC}. In an embodiment, digital filter 260 is digital nulling filter that subjects the digital signal S_{ADC} to a digital nulling operation in which the remaining unwanted frequency components in digital signal S_{ADC} are attenuated and that leaves wanted frequency component S_{wanted} substantially unchanged. Such nulling is described in above-mentioned United States patent application publication no. 2006/0003723. In another embodiment, digital filter 260 is an adaptive digital nulling filter whose filter characteristics can be changed depending on the frequencies of RF input signal Sᵢₙ and the repetition rate and ON time of gate switch 240 to align zeroes in the response of the nulling filter with the unwanted frequency components in digital signal S_{ADC}. In other embodiments of receiver system 170, digital filter 260 is omitted.

Processing system 180 is connected to receive filtered signal Sₙᵤₗₗ from digital filter 260. Processing system 180 processes the filtered signal Sₙᵤₗₗ to determine the one or more characteristics of the DUT. Processing system 180 outputs a result signal Sᵣₑₛᵤₗₜ that represents the one or more characteristics of the DUT.

Referring again to FIG. 2A, VNA 200 will now be described in greater detail. Amplifier 210 receives RF input signal Sᵢₙ from RF input 110. RF input signal Sᵢₙ comprises a thermal noise component N_{TH}. Amplifier 210 amplifies the RF input signal Sᵢₙ by gain Gₐₘₚ. The gain Gₐₘₚ of amplifier 210 is chosen such that the maximum power of amplified signal Sₐₘₚ is greater than the maximum input power of receiver system 170. In amplifying RF input signal Sᵢₙ, amplifier 210 also amplifies thermal noise component N_{TH} by gain Gₐₘₚ to generate a noise component Nₐₘₚ of amplified signal Sₐₘₚ. Amplifier 210 outputs amplified signal Sₐₘₚ to the input of gate switch 240.

Gate switch 240 receives amplified signal Sₐₘₚ from the output of amplifier 210. Gate switch 240 subjects amplified signal Sₐₘₚ to repetitive gating, as described above, to generate gated signal S_{gate}. In its ON state, gate switch 240 passes amplified signal Sₐₘₚ to the input of bandpass filter 220. In its OFF state, gate switch 240 prevents amplified signal Sₐₘₚ from passing to the input of bandpass filter 220. In subjecting amplified signal Sₐₘₚ to repetitive gating, gate switch 240 additionally subjects the noise component Nₐₘₚ of amplified signal Sₐₘₚ to repetitive gating. Consequently, gated signal S_{gate} includes a noise component N_{gate}.

Gate switch 240 operates with pre-determined repetition rate (1/P), pre-determined ON time (W), and, hence, predetermined duty cycle W/P. Repetitively operating gate switch 240 with the duty cycle W/P reduces the average power of the noise component N_{gate} of gated signal S_{gate} relative to that of the noise component Nₐₘₚ of amplified signal Sₐₘₚ. In its ON state, gate switch 240 passes noise component Nₐₘₚ to the input of band-pass filter 220. In its OFF state, gate switch 240 prevents noise component Nₐₘₚ from passing to the input of band-pass filter 220. Consequently, the average power of the noise component N_{gate} of gated signal S_{gate} output by gate switch 240 depends on the duty cycle of the gate switch. The input of band-pass filter 220 is additionally subject to thermal noise N_{TH} regardless of the state of gate switch 240.

The pass band of bandpass filter 220 has a center frequency nominally equal to the frequency of wanted frequency component S_{wanted}. Circuits and devices suitable for use as bandpass filter 220 are known in the art and can be used. Bandpass filter 220 receives gated signal S_{gate} from the output of gate switch 240 and passes those frequency components of gated signal S_{gate} that have frequencies within its pass band to receiver system 170 with negligible signal loss. The frequency components of gated signal S_{gate} having frequencies within the pass band of band-pass filter 220 include wanted frequency component S_{wanted}, i.e., a frequency component having a frequency equal to that of RF input signal Sᵢₙ. Bandpass filter 220 significantly attenuates frequency components of the gated signal S_{gate} having frequencies outside its pass band. Such frequency components include, e.g., harmonics of pulse-modulated RF input signal Sᵢₙ and pulse modulation harmonics centered on the frequency of the RF input signal and separated in frequency therefrom by integer multiples of the repetition rate 1/P of gate switch 240.

Bandpass filter 220 additionally attenuates the noise component N_{gate} of gated signal S_{gate} at frequencies outside its pass band. However, in embodiments in which the pass band of band-pass filter 220 is broader than the bandwidth of receiver system 170, as is typical, the attenuation of noise component N_{gate} has a negligible effect on the noise component of filtered signal Sₙᵤₗₗ.

Bandpass filter 220, as in all filters, has an inherent finite rise-time that is inversely proportional to the width of its pass band. In response to each pulse of gated signal S_{gate} received at its input, bandpass filter 220 outputs a corresponding pulse of selected signal S_{select}. The pulses of selected signal S_{select} do not instantaneously reach a maximum power substantially equal to the maximum instantaneous power of gated signal S_{gate}. Instead, the pulses of selected signal S_{select} take a short but non-negligible time to rise to their maximum power. This time is known as the rise-time of the pulses. The rise-time of the pulses is typically defined as the time taken for the power of the pulses to rise from a specified low value to a specified high value. In one example, the specified low value and the specified high value are 10% and 90%, respectively, of maximum power.

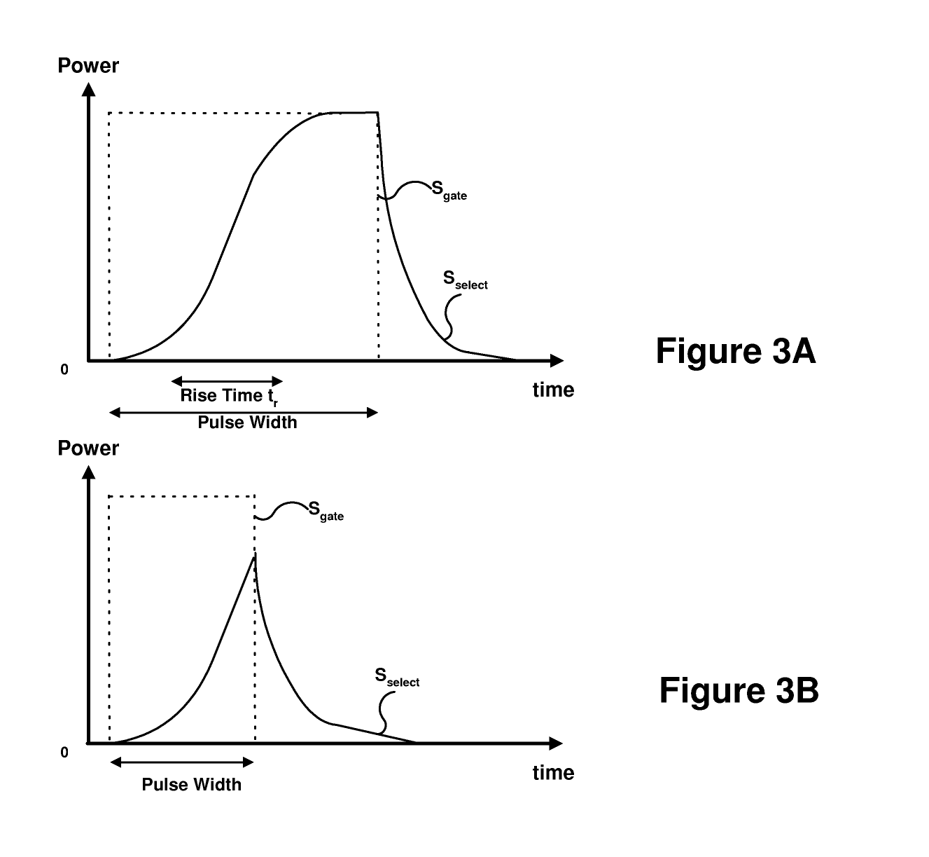

FIGS. 3A and 3B are graphs that illustrate the effect of the finite rise-time tᵣ, of bandpass filter 220 on the maximum power of the pulses of selected signal S_{select} for different pulse widths of gated signal S_{gate}. FIG. 3A shows an example in which the pulse width of the gated signal S_{gate} is about twice the rise-time tᵣ of bandpass filter 220. In this, the maximum power of selected signal S_{select} differs negligibly from that of gated signal S_{gate}. FIG. 3B shows an example in which the pulse width of gated signal S_{gate} is about the same as the rise-time tᵣ of the bandpass filter 220. In this, the maximum power of selected signal S_{select} is significantly less than that of gated signal S_{gate}.

Bandpass filter 220 reduces the maximum power of selected signal S_{select} relative to that of gated signal S_{gate} by attenuating frequency components in gated signal S_{gate} other than wanted frequency component S_{wanted}, as described above. On the other hand, bandpass filter 220 negligibly attenuates the wanted frequency component S_{wanted} in selected signal S_{select}.

As noted above, in the example of receiver system 170 shown in FIG. 2B, ADC 150 has a maximum input power that defines the maximum input power of the receiver system. In other examples, a component of receiver system 170 other than ADC 150 defines the maximum input power of the receiver system.

For a given maximum power of gated signal S_{gate}, the relationship between the ON time W of gate switch 240 and the rise time of bandpass filter 220 determines the maximum power of selected signal S_{select} input to ADC 150. ON time W is set such that the maximum power of selected signal S_{select} is less than the maximum input power of receiver system 170. Alternatively, the maximum power of selected signal S_{select} is determined by setting the gain Gₐₘₚ of amplifier 210 or by setting the repetition rate 1/P of gate switch 240, or by setting an appropriate combination of the ON time W and repetition rate 1/P of gate switch 240, and the gain Gₐₘₚ of amplifier 210. In another alternative, the bandwidth of bandpass filter 220 is set to obtain a rise time tᵣ that prevents the maximum power of selected signal S_{select} from exceeding the maximum input power of receiver system 170 at a given ON time of gate switch 240.

In an exemplary implementation of VNA 200, amplifier 220 has a power gain Gₐₘₚ of 20 dB, gate switch 240 has an ON time W of 1 μs and a repetition gate 1/P of 1 kHz, and bandpass filter 220 has a rise-time tᵣ of 100 μs and a pass bandwidth of 5 kHz.

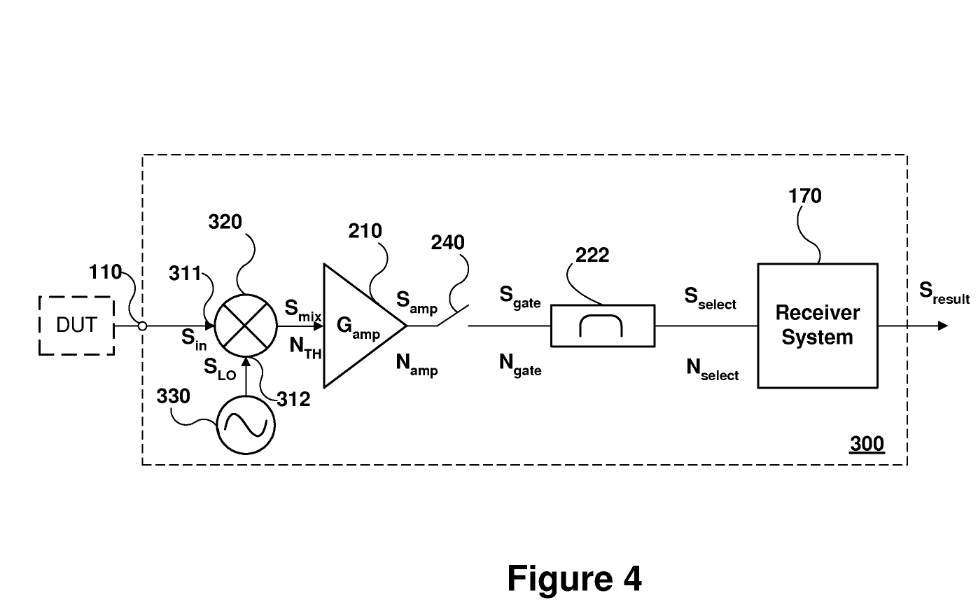

In VNA 200, the frequency of the RF input signal received from the DUT must lie within the pass band of bandpass filter 210. This allows the characteristic of the DUT to be measured at a single, fixed frequency of the RF input signal, or over a relatively narrow frequency range of the RF input signal. It is often desirable to determine the characteristic of the DUT at one or more frequencies of the RF input signal independent of the filter characteristics of the bandpass filter. FIG. 4 is a block diagram showing an example of a VNA 300 in accordance with another embodiment of the invention. VNA 300 is capable of determining a characteristic of the device under test (DUT) at one or more frequencies of the RF input signal independent of the filter characteristics of the bandpass filter.

VNA 300 is structurally identical to VNA 200 except that a mixer 320 is interposed between the RF input 110 and the input of the amplifier 210. The mixer additionally receives a local-oscillator signal from a local oscillator 330. By changing frequency of the local-oscillator signal in accordance with the frequency of the RF input signal, the characteristic of the DUT can be determined at the frequency of the RF input signal independently of the filter characteristics of the bandpass filter. Elements of VNA 300 corresponding to those of VNA 200 described above with reference to FIG. 2A are indicated using the same reference numerals and will not be described again in detail.

Mixer 320 has two inputs, first input 311 and second input 312. First input 311 is connected to the RF input 110. Second input 312 is connected to local oscillator 330 and receives the local-oscillator signal S_{LO} generated by local oscillator 330. Mixer 320 mixes the RF input signal Sᵢₙ and local-oscillator signal S_{LO} to generate a mixed signal Sₘᵢₓ. Mixer 320 outputs the mixed signal Sₘᵢₓ to amplifier 210.

Mixer 320 is a non-linear device that receives RF input signal Sᵢₙ and local-oscillator signal S_{LO} at respective inputs. RF input signal Sᵢₙ and local-oscillator signal S_{LO} have different frequencies. Mixer 320 mixes the signals to generate mixed signal Sₘᵢₓ and outputs the mixed signal at its output. Circuits suitable for use as mixer 320 are known in the art and can be used.

Mixed signal Sₘᵢₓ generated by mixer 320 has frequency components at several frequencies. The frequency components include a sum frequency component at a frequency equal to the sum of the frequencies of RF input signal Sᵢₙ and local-oscillator signal S_{LO} and a difference frequency component at a frequency equal to the difference between the frequencies of RF input signal Sᵢₙ and local-oscillator signal S_{LO}. The frequency components of mixed signal Sₘᵢₓ additionally include frequency components at frequencies equal to the frequencies of RF input signal Sᵢₙ, local-oscillator signal S_{LO}, and harmonics and products (through mixing) of these frequency components. In some applications, the RF input signal Sᵢₙ is a pulse-modulated signal, and is composed of a fundamental frequency component and pulse modulation harmonics separated in frequency from the fundamental frequency component by integer multiples of the repetition frequency of the pulse modulation. In this case, mixed signal Sₘᵢₓ additionally comprises frequency components at frequencies that are the sum of and the difference between the frequencies of the frequency components of RF input signal Sᵢₙ and the frequency of the local oscillator signal S_{LO}. The mixed signal Sₘᵢₓ generated by mixer 320 also comprises a thermal noise component N_{TH}.

Regardless of whether RF input signal Sᵢₙ is a pulse-modulated signal, one of the frequency components of mixed signal Sₘᵢₓ is wanted frequency component S_{wanted}. The frequency of wanted frequency component S_{wanted} is typically the sum of, or the difference between, the frequencies of the fundamental frequency component of input signal Sᵢₙ and local oscillator signal S_{LO}. The mixer 320 outputs the mixed signal Sₘᵢₓ to amplifier 210. Amplifier 210, gate switch 240 and receiver system 170 are similar to corresponding elements of VNA 200 described above with reference to FIGS. 2A and 2B. In VNA 300, a bandpass filter 222 is interposed between gate switch 240 and receiver system 170. Bandpass filter 222 is similar in structure and function to bandpass filter 220 of VNA 200, but its pass band typically has a different center frequency. The frequency of local-oscillator signal S_{LO} is set in relation to the frequency of RF input signal Sᵢₙ such that the frequency of wanted frequency component S_{wanted} that constitutes part of mixed signal Sₘᵢₓ lies within the pass band of bandpass filter 222.

Amplifier 210, gate switch 240, bandpass filter 222 and receiver system 170 collectively process mixed signal Sₘᵢₓ to determine a characteristic of the DUT in a manner similar to the way amplifier 210, gate switch 240, bandpass filter 220 and receiver system 170 collectively process RF input signal Sᵢₙ in VNA 200 described above with reference to FIGS. 2A and 2B. The processing of mixed signal Sₘᵢₓ will therefore not be described here.

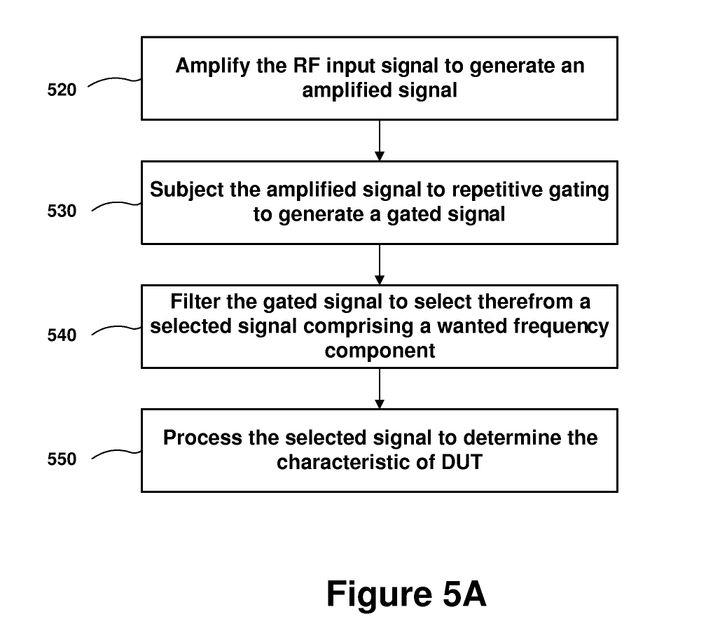

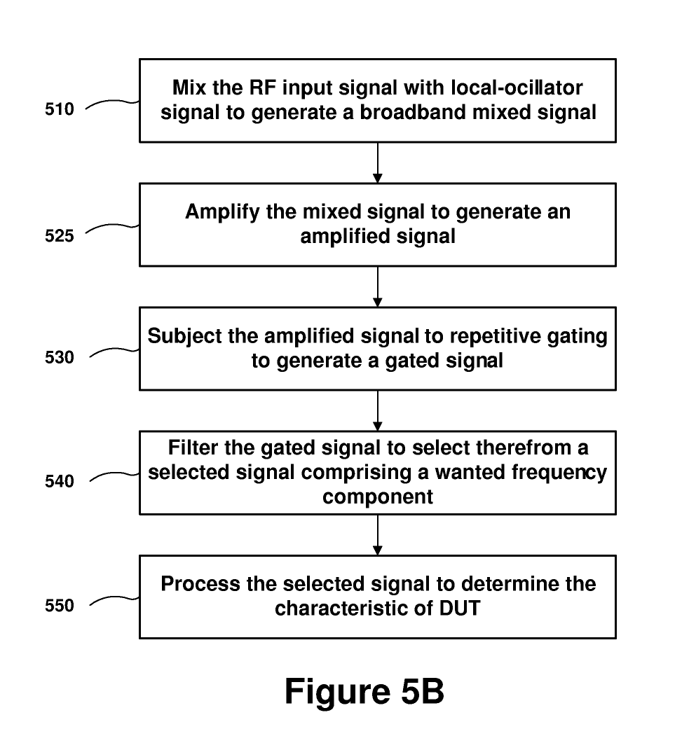

FIG. 5A is a flowchart showing an example of a method in accordance with an embodiment of the invention for determining a characteristic of a device under test DUT from an RF input signal received from the DUT. In block 520, the RF input signal Sᵢₙ received from the DUT is amplified to generate an amplified signal Sₐₘₚ. The amplified signal is higher in power than RF input signal Sᵢₙ. In block 530, amplified signal Sₐₘₚ is subject to repetitive gating to generate a gated signal S_{gate}. The gating has a defined ON time. In block 540, gated signal S_{gate} is filtered to select therefrom a selected signal S_{select} that comprises a wanted frequency component. In block 550, the selected signal S_{select} is processed to determine the characteristic of the DUT. The processing has a defined maximum input power. The filtering performed in block 540 has a rise-time in relation to the ON time of the gating such that the selected signal S_{select} has a maximum power that does not exceed the maximum input power of the processing performed in block 550.

In an example of the processing performed in block 550, the selected signal S_{select} is digitized to produce a digital signal S_{ADC}. The digital signal S_{ADC} is subject to digital null-filtering in a manner similar to that disclosed in United States patent application publication number 2006/0003723. The digital null-filtering removes from digital signal S_{ADC} those unwanted frequency components that remain after gated signal S_{gate} has been subject to bandpass filtering that selects a wanted frequency component that can be processed to determine the one or more characteristics of the DUT.

In the method described above with reference to FIG. 5A, the RF input signal Sᵢₙ has a fixed frequency that depends on the filter characteristic of the filtering performed in block 540. In other applications, it is desirable to be able to measure the characteristic of the DUT at one or more frequencies of the RF input signal independent of the filter characteristic of the filtering. FIG. 5B is a flow chart showing an example of another method in accordance with an embodiment of the invention for determining a characteristic of a device under test DUT from an RF input signal received from the DUT. The method shown in FIG. 5B allows the characteristic of the DUT to be determined at an arbitrary frequency of the RF input signal and/or at more than one frequency of the RF input signal independently of the filter characteristic of the filtering. In block 510, the RF input signal is mixed with a local-oscillator signal to generate broadband mixed signal Sₘᵢₓ. In block 525, mixed signal Sₘᵢₓ is amplified to generate amplified signal Sₐₘₚ. Blocks 530, 540 and 550 are then performed as described above with reference to FIG. 5A. The filtering performed in block 540 is performed with a filter characteristic independent of the frequency to the RF input signal. Instead, the filter characteristic depends on the frequency of the above-described wanted frequency component S_{wanted}.

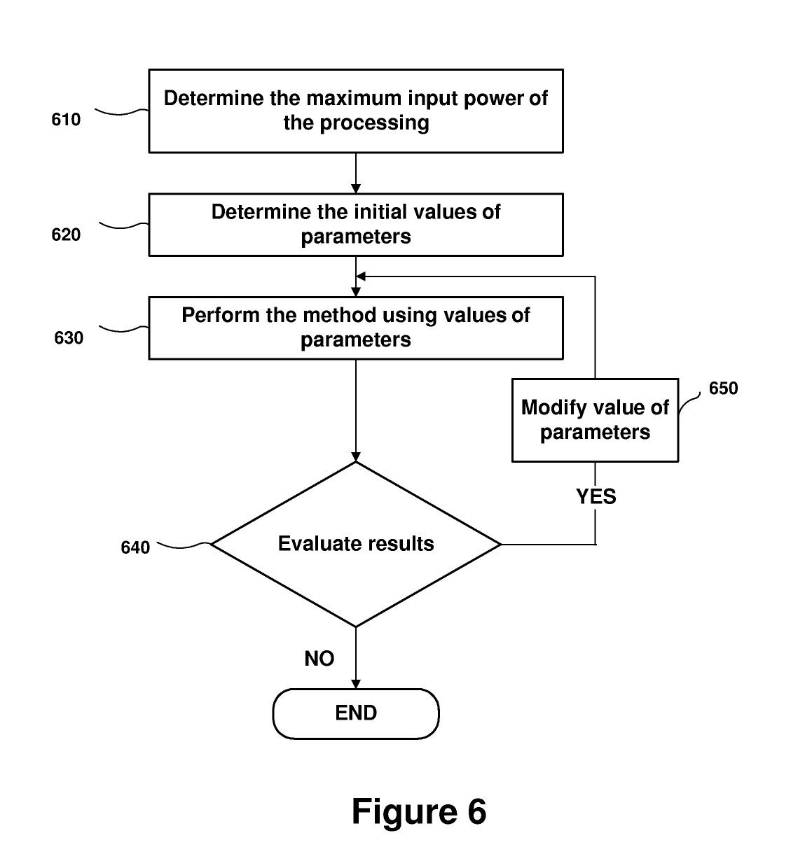

FIG. 6 is a flowchart showing an example of a method of selecting parameters used in performing the method examples described above with reference to FIGS. 5A and 5B. In block 610, the maximum input power of the processing performed in block 550 of FIGS. 5A and 5B is determined. In block 620, preliminary parameters are selected for the gain of the amplifying performed in block 520 of FIG. 5A and block 525 of FIG. 5B, the repetition rate and ON time of the gating performed in block 530 of FIGS. 5A and 5B, and the pass bandwidth of the filtering performed in block 540 of FIGS. 5A and 5B. In the preliminary selection, the gain is chosen to make the maximum power of the amplified signal greater than the maximum input power of the processing performed in block 550 of FIGS. 5A and 5B. The ON time of the gating is set in relation to the rise-time of the filtering performed in block 540 such that the maximum power of the selected signal obtained by the filtering will be less than the maximum input power of the processing performed in block 550. The rise-time of the filtering depends on the pass bandwidth of the filtering, as described above. In block 630, the method described above with reference to FIGS. 5A and 5B is performed using the preliminary parameters defined in block 620. In block 640, the result of using the preliminary parameters on the maximum power of the selected signal is evaluated. If the maximum power of the selected signal is less than the maximum input power of the processing performed in block 550, execution of the method terminates. Otherwise, execution advances to block 650, where at least one of the parameters, i.e., the gain, the repetition rate, the ON time and the filter pass bandwidth, is modified. Execution then returns to block 630. Blocks 630 and 640 are repeated until a YES result is obtained in block 640. Additionally, at least one of the parameters can be changed if the maximum power of the selected signal is determined in block 640 be significantly less than maximum input power of the processing.

The signal-to-noise ratio of VNA 300 described above with reference to FIG. 4 will now be described. The signal-to-noise ratio described hereafter is a function of the power of the signal divided by the noise power. Referring again to FIG. 4, mixer 320 mixes the RF input signal Sᵢₙ received from the DUT via RF input 110 with the local-oscillator signal S_{LO} received from local oscillator 330 to generate broadband mixed signal Sₘᵢₓ. RF input signal Sᵢₙ has a signal power Pᵢₙ. Broadband mixed signal Sₘᵢₓ has a signal power Pₘᵢₓ and comprises thermal noise component N_{TH}.

Amplifier 210 amplifies mixed signal Sₘᵢₓ to generate an amplified signal Sₐₘₚ that is higher in power than the mixed signal Sₘᵢₓ. The power Pₐₘₚ of amplified signal Sₐₘₚ is given by:

Pₐₘₚ=Gₐₘₚ*Pₘᵢₓ=Gₘᵢₓ*Gₐₘₚ*Pᵢₙ

where Gₘᵢₓ and Gₐₘₚ are the power gains of mixer 320 and amplifier 210, respectively.

Amplifying mixed signal Sₘᵢₓ also amplifies thermal noise component N_{TH} by gain Gₐₘₚ to generate the noise component Nₐₘₚ of amplified signal Sₐₘₚ. Thermal noise component N_{TH} has a noise power per hertz (Hz) of bandwidth n_{TH} equal to the product of k, Boltzmann's constant, and T, the absolute temperature. The power per Hz nₐₘₚ of the noise component Nₐₘₚ of amplified signal Sₐₘₚ is given by.

nₐₘₚ=Gₐₘₚ*n_{TH}=Gₐₘₚ*kT

Gate switch 240 subjects amplified signal Sₐₘₚ to repetitive gating in which gate switch 240 in its ON state passes a temporal portion of amplified signal Sₐₘₚ as gated signal S_{gate} and in its OFF state blocks the temporal remainder of amplified signal Sₐₘₚ. The average power P_{gate} of gated signal S_{gate} depends on the duty cycle (W/P) of gate switch 240 and is given by:

$${P}_{gate} = ( \frac{W}{P} ) * {P}_{amp}$$

Gated signal S_{gate} comprises a noise component N_{gate}. Bandpass filter 222 receives noise component N_{gate} as part of gated signal S_{gate} when gate switch 240 is in its ON state. When gate switch 240 is in its OFF state, gated signal S_{gate}, including noise component N_{gate}, is blocked from bandpass filter 222, but the input of bandpass filter 222 is subject to thermal noise N_{TH}. Consequently, the average noise power per Hz n_{gate} of noise component N_{gate} at the input of bandpass filter 222 is given by:

$$\begin{matrix}{n}_{gate} = \frac{{n}_{TH} * ( P - W ) + {n}_{amp} * W}{P} \\ = \frac{{n}_{TH} * ( P - W ) + {G}_{amp} * {n}_{TH} * W}{P} \\ = {n}_{TH} * [ 1 + \frac{W * ( {G}_{amp} - 1 )}{P} ] \\ = kT * [ 1 + ( {G}_{amp} - 1 ) ( \frac{W}{P} ) ]\end{matrix}$$

The input of receiver system 170 has a maximum input power that imposes a finite limit on the power of the input signal to the receiver system. Bandpass filter 222 attenuates gated signal S_{gate} to generate selected signal S_{select} that falls within the finite limit. Selected signal S_{select} constitutes the input signal to the receiver system 170.

The attenuation of gated signal S_{gate} by bandpass filter 222 depends on the relationship between the ON time W of gate switch 240 and the rise time tᵣ of band-pass filter 222. The ON time W of gate switch 240 is set relative to the rise-time tᵣ of bandpass filter 222 such that bandpass filter 222 attenuates the maximum power of selected signal S_{select} input to receiver system 170 to a power less than the maximum input power of the receiver system. The maximum power P_{select, max} of selected signal S_{select} is given by:

$${P}_{select , max} = {G}_{mix} * {G}_{amp} * ( \frac{W}{{t}_{r}} ) * {P}_{i n}$$

In an example in which the maximum input power of receiver system 170 is equal to Gₘᵢₓ*Pᵢₙ, the factor

$${G}_{amp} * ( \frac{W}{{t}_{r}} )$$

has a maximum value of unity, i.e.:

$${G}_{amp} * ( \frac{W}{{t}_{r}} ) \leq 1$$

From this, the maximum gain G_{amp,max} of amplifier 210 is given by:

$${G}_{amp , max} \leq ( \frac{{t}_{r}}{W} ) .$$

In another embodiment, bandpass filter 222 operates to remove frequency components of gated signal S_{gate} that lie outside its pass band. The wanted frequency component S_{wanted} in the gated signal S_{gate} remains unattenuated and is output by the band-pass filter as a frequency component of selected signal S_{select}. Additionally, bandpass filter 222 attenuates gated noise component N_{gate} at frequencies outside its passband. According to Parseval's theorem, the power P_{wanted} of the wanted frequency component S_{wanted} in the selected signal S_{select} depends on the duty cycle (W/P) of gate switch 240, and is given by:

$${P}_{wanted} = {( \frac{W}{P} )}^{2} * {P}_{amp} = {G}_{mix} * {G}_{amp} * {( \frac{W}{P} )}^{2} * {P}_{i n}$$

In the examples described above, the power per Hz n_{select} of the noise component N_{select} of selected signal is the same as the noise power per Hz n_{gate} of the noise component N_{gate} of gated signal S_{gate}:

$${n}_{select} = {n}_{gate} = kT * [ 1 + ( {G}_{amp} - 1 ) ( \frac{W}{P} ) ]$$

Referring now to FIG. 2B, after ADC 150 digitizes selected signal S_{select} to generate digital signal S_{ADC}, digital signal S_{ADC} is subject to digital filtering by digital filter 260. In the filtering operation, the unwanted frequency components remaining in selected signal S_{select} are attenuated. Digital filter 260 outputs wanted frequency component S_{wanted} as substantially the only frequency component of filtered signal Sₙᵤₗₗ. The power P_{wanted} of the wanted frequency component S_{wanted} in filtered signal Sₙᵤₗₗ remains the same as in selected signal S_{select}. Filtered signal Sₙᵤₗₗ additionally comprises noise component Nₙᵤₗₗ. The noise component N_{select} of selected signal S_{select} passes through digital filter 260 without loss to become filtered noise component Nₙᵤₗₗ. The power Pₙᵤₗₗ of filtered signal Sₙᵤₗₗ and the power per Hz nₙᵤₗₗ of noise component Nₙᵤₗₗ are given by:

$${P}_{null} = {P}_{wamted} = {( \frac{W}{P} )}^{2} * {P}_{amp} = {G}_{mix} * {G}_{amp} * {( \frac{W}{P} )}^{2} * {P}_{i n}$$

$${n}_{null} = {n}_{select} = kT * [ 1 + ( {G}_{amp} - 1 ) ( \frac{W}{P} ) ]$$

As noted above, the bandwidth B of digital filter 260 is narrower than the pass bandwidth of band-pass filter 222 and therefore defines the noise bandwidth of VNA 200. The power per Hz nₙᵤₗₗ of the noise component Nₙᵤₗₗ of filtered signal Sₙᵤₗₗ is given by:

$${n}_{null} = kTB * [ 1 + ( {G}_{amp} - 1 ) ( \frac{W}{P} ) ]$$

Processing system 180 receives filtered signal Sₙᵤₗₗ from digital filter 260. Processing system processes filtered signal Sₙᵤₗₗ to determine the one or more characteristics of the DUT.

At the input of the processing system 180 of VNA 300, filtered signal Sₙᵤₗₗ has a signal-to-noise ratio (SNR₃₀₀) given by:

$$\begin{matrix}{SNR}_{300} = \frac{{P}_{null}}{{n}_{null}} \\ = \frac{{G}_{mix} * {G}_{amp} * {( \frac{W}{P} )}^{2} * {P}_{i n}}{kTB * [ 1 + ( {G}_{amp} - 1 ) ( \frac{W}{P} ) ]} \\ = \frac{{G}_{mix} * {( \frac{W}{P} )}^{2} * {P}_{i n}}{kTB} * \frac{{G}_{amp}}{1 + ( {G}_{amp} - 1 ) ( \frac{W}{P} )} \\ = {( \frac{W}{P} )}^{2} * \frac{{P}_{i n}}{kTB} * \frac{{G}_{mix} * {G}_{amp}}{1 + ( {G}_{amp} - 1 ) ( \frac{W}{P} )}\end{matrix}$$

The signal-to-noise ratio of filtered signal Sₙᵤₗₗ in VNA 300 is greater than that of filtered signal Sₙᵤₗₗ in VNA 100 described above with reference to FIG. 1. An analysis similar to that described above will now be described with reference to VNA 100.

Referring to FIG. 1, the power Pₘᵢₓ of mixed signal Sₘᵢₓ generated by mixer 120 is given by:

Pₘᵢₓ=Gₘᵢₓ*Pᵢₙ

where Gₘᵢₓ is the gain of mixer 120.

The power per Hz n_{TH} of thermal noise component N_{TH} output by mixer 120 is given by:

n_{TH}=kT

The average power P_{gate} of gated signal S_{gate} output by gate switch 140 is given by:

$${P}_{gate} = ( \frac{W}{P} ) * {P}_{mix}$$

The power of the wanted frequency component S_{wanted} in gated signal S_{gate} according to Parseval's theorem is given by:

$${P}_{wanted} = {( \frac{W}{P} )}^{2} * {P}_{mix}$$

Gated signal S_{gate} comprises noise component N_{gate} that is equal in power to thermal noise component N_{TH}. In the ON state of gate switch 140, ADC 150 receives noise component N_{gate} as part of gated signal S_{gate}. In the OFF state of gate switch 140, gated noise component N_{gate} is isolated from ADC 150, but the input of ADC 150 is subject to thermal noise N_{TH}. Since the power per Hz of noise component N_{gate} is equal to that of thermal noise N_{TH}, the average power per Hz n_{gate} of the noise component N_{gate} of gated signal S_{gate} received by ADC 150 is equal to that of thermal noise N_{TH}, i.e.,

n_{gate}=n_{TH}=kT

In VNA 100, ADC 150, null filter 160 and processor 180 perform the same functions as the corresponding elements of VNA 200. Digital signal S_{ADC} generated by ADC 150 comprises a noise component N_{ADC}. The average power per Hz n_{ADC} of the noise component N_{ADC} is equal to the average power per Hz n_{gate} of the noise component N_{gate} of gated signal S_{gate}, i.e., kT. Null filter 160 subjects digital signal S_{ADC} to nulling to eliminate unwanted frequency components, while retaining the wanted frequency component S_{wanted}, to generate filtered signal Sₙᵤₗₗ. Null filter 160 passes the noise component N_{ADC} of digital signal S_{ADC} without loss to provide the noise component Nₙᵤₗₗ of filtered signal Sₙᵤₗₗ. Noise component Nₙᵤₗₗ has the same average power per Hz nₙᵤₗₗ as the noise component N_{ADC}:

nₙᵤₗₗ=n_{ADC}=n_{gate}=kT

Since ADC 150 and null filter 160 do not attenuate the wanted frequency component S_{wanted} of gated signal S_{gate}, the power Pₙᵤₗₗ of the wanted frequency component in filtered signal Sₙᵤₗₗ is the same as that P_{wanted} of the wanted frequency component in gated signal S_{gate}:

$${P}_{null} = {P}_{wanted} = {( \frac{W}{P} )}^{2} * {P}_{mix}$$

Nulling filter 160 has a bandwidth B that defines the noise bandwidth of VNA 100. The power nₙᵤₗₗ of noise component Nₙᵤₗₗ is given by:

nₙᵤₗₗ=kTB

Thus, at the input of the processing system 180 of VNA 100, filtered signal Sₙᵤₗₗ has a signal-to-noise ratio (SNR₁₀₀) given by:

$${SNR}_{100} = \frac{{P}_{null}}{{n}_{null}} = {( \frac{W}{P} )}^{2} * \frac{{P}_{mix}}{kTB} = {( \frac{W}{P} )}^{2} * \frac{{G}_{mix} * {P}_{i n}}{kTB}$$

The signal-to-noise ratio calculated above for VNA 300 is greater than that calculated for VNA 100 by a factor:

$$\frac{{G}_{amp}}{1 + ( {G}_{amp} - 1 ) ( \frac{W}{P} )}$$

In an example in which Gₘᵢₓ=1, Gₐₘₚ=100 (20 dB) and gate switch 240 has a duty cycle of 0.01 (1%), the signal-to-noise ratio of VNA 300 is greater than that of VNA 100 by the factor:

$$( \frac{100}{1 + ( 99 * 0.01 )} ) = 50.25 , or 17 dB$$

The signal-to-noise ratio of VNA 200 described above with reference to FIGS. 2A and 2B is similar that of VNA 300 and will not be described in detail. In VNA 200, the input to amplifier 210 is the RF input signal Sᵢₙ from RF input 110 rather than the mixed signal Sₘᵢₓ in VNA 300. By substituting Pᵢₙ for Pₘᵢₓ in the signal-to-noise ratio analysis for VNA 300, the signal-to-noise ratio for VNA 200 is given by

$$\begin{matrix}{SNR}_{200} = \frac{{P}_{null}}{{n}_{null}} \\ = \frac{{G}_{amp} * {( \frac{W}{P} )}^{2} * {P}_{i n}}{kTB * [ 1 + ( {G}_{amp} - 1 ) ( \frac{W}{P} ) ]} \\ = \frac{{( \frac{W}{P} )}^{2} * {P}_{i n}}{kTB} * \frac{{G}_{amp}}{1 + ( {G}_{amp} - 1 ) ( \frac{W}{P} )} \\ = {( \frac{W}{P} )}^{2} * \frac{{P}_{i n}}{kTB} * \frac{{G}_{amp}}{1 + ( {G}_{amp} - 1 ) ( \frac{W}{P} )}\end{matrix}$$

Comparing the signal-to-noise ratio calculated above for VNA 200 with that calculated for VNA 100, the signal-to-noise ratio for VNA 200 is greater than that calculated for VNA 100 by a factor:

$$\frac{{G}_{amp}}{1 + ( {G}_{amp} - 1 ) ( \frac{W}{P} )}$$

This factor is identical to that of an example of VNA 300 in which mixer 320 has a gain Gₘᵢₓ of unity.

This disclosure describes the invention in detail using illustrative embodiments. However, the invention defined by the appended claims is not limited to the precise embodiments described.

I claim:

1. A system for determining a characteristic of a device under test (DUT) in response to an RF input signal received from the DUT, the system comprising:
an RF input operable to receive the RF input signal;
a receiver system operable to determine the characteristic of the DUT from a receiver input signal, the receiver system having a defined maximum input power; and
circuit elements connected in series between the RF input and the receiver system, the circuit elements comprising:
an amplifier operable to generate an amplified signal by amplifying the RF input signal, the amplified signal having a maximum power that exceeds the maximum input power of the receiver system;
a gate switch having a repetitive ON time, the gate switch operable to generate a gated signal by subjecting the amplified signal to repetitive gating, and
a bandpass filter configured to select from the gated signal a selected signal comprising a wanted frequency component, the bandpass filter having a rise-time in relation to the ON time of the gate switch such that the selected signal has a maximum power that does not exceed the maximum input power of the receiver system.

2. The system of claim 1, additionally comprising a mixer interposed between the RF input and the amplifier, the mixer operable to generate a mixed signal by mixing the RF input signal with a local-oscillator signal.

3. The system of claim 2, in which:
the RF input signal and the local-oscillator signal have respective frequencies;
the mixed signal comprises a sum frequency component and a difference frequency component, the sum frequency component at a frequency equal to a sum of the frequencies of the RF input signal and the local-oscillator signal, the difference frequency component at a frequency equal to a difference between the frequencies of the RF input signal and the local-oscillator signal; and
the band-pass filter has a pass band within which the frequency of the sum frequency component lies.

4. The system of claim 2, in which:
the RF input signal and the local-oscillator signal have respective frequencies;
the mixed signal comprises a sum frequency component and a difference frequency component, the sum frequency component at a frequency equal to a sum of the frequencies of the RF input signal and the local-oscillator signal, the difference frequency component at a frequency equal to a difference between the frequencies of the RF input signal and the local-oscillator signal; and
the band-pass filter has a pass band within which the frequency of the difference frequency component lies.

5. The system of claim 1, in which the receiver system comprises an analog-to-digital converter (ADC), in which the ADC has a full-scale input power that defines the maximum input power of the receiver system.

6. The system of claim 5, in which:
the ADC has a digital output; and
the receiver system additionally comprises a digital filter connected to the digital output of the ADC, the digital filter operable to generate a filtered signal by removing unwanted frequency components output by the ADC.

7. The system of claim 6, in which the digital filter is an adaptive nulling filter.

8. The system of claim 6, in which the receiver system additionally comprises a processor connected to receive the filtered signal from the digital filter and operable to determine the characteristic of the DUT from the filtered signal.

9. The system of claim 1, in which the amplifier has a gain that depends on the rise-time of the bandpass filter and the ON time of the gate switch.

10. The system of claim 1, in which the gate switch has a defined duty cycle.

11. The system of claim 1, in which the RF input signal is a pulse-modulated signal.

12. A method for determining a characteristic of a device under test (DUT) from an RF input signal received from the DUT, the method comprising:
amplifying the RF input signal to generate an amplified signal;
subjecting the amplified signal to repetitive gating to generate a gated signal, the gating having an ON time;
filtering the gated signal to select therefrom a selected signal comprising a wanted frequency component; and
processing the selected signal to determine the characteristic of the DUT, the processing having a defined maximum input power, in which:
the filtering has a rise-time in relation to the ON time of the gating such that the selected signal has a maximum power that does not exceed the maximum input power of the processing.

13. The method of claim 12, in which:
the method additionally comprises mixing the RF input signal with a local-oscillator signal to generate a mixed signal; and
the amplifying comprises amplifying the mixed signal instead of the RF input signal to generate the amplified signal.

14. The method of claim 13, in which:
the RF input signal and the local-oscillator signal have respective frequencies;
the mixed signal comprises a sum frequency component and a difference frequency component, the sum frequency component at a frequency equal to a sum of the frequencies of the RF input signal and the local-oscillator signal, the difference frequency component at a frequency equal to a difference between the frequencies of the RF input signal and the local-oscillator signal; and
the filtering is performed with a bandpass characteristic having a pass band within which the frequency of the sum frequency component lies.

15. The method of claim 13, in which:
the RF input signal and the local-oscillator signal have respective frequencies;
the mixed signal comprises a sum frequency component and a difference frequency component, the sum frequency component at a frequency equal to a sum of the frequencies of the RF input signal and the local-oscillator signal, the difference frequency component at a frequency equal to a difference between the frequencies of the RF input signal and the local-oscillator signal; and
the filtering is performed with bandpass characteristic having a pass band within which the frequency of the difference frequency component lies.

16. The method of claim 12, in which:
the amplifying comprises amplifying the RF input signal with a defined gain; and
the maximum power of the selected signal depends on the gain of the amplifying and the ON time of the gating.

17. The method of claim 12, in which the processing comprises subjecting the selected signal to analog-to-digital conversion, the analog-to-digital conversion having a full-scale input power that defines the maximum input power of the processing.

18. The method of claim 17, in which:
subjecting the selected signal to analog-to-digital conversion generates a digital signal; and
the processing additionally comprises generating a filtered signal by nulling unwanted frequency components in the digital signal.

19. The method of claim 18, in which the nulling is adaptive nulling.

20. The method of claim 18, in which the processing additionally comprises processing the filtered signal to determine the characteristic of the DUT.

21. The method of claim 12, in which the amplifying comprises amplifying the RF input signal to a power level greater than the maximum input power of the processing.

22. The method of claim 12, in which the RF input signal is a pulse-modulated signal.
